(19) United States
(12) Patent Application Publication
(10) Pub. No.: US 2013/0121092 A1
(43) Pub. Date: May 16, 2013

(54) SEMICONDUCTOR DEVICE INCLUDING PLURAL SEMICONDUCTOR CHIPS STACKED TO ONE ANOTHER

(71) Applicant: Elpida Memory, Inc., Tokyo (JP)

(72) Inventor: Masashi Ogasawara, Tokyo (JP)

(73) Assignee: Elpida Memory, Inc., Tokyo (JP)

(21) Appl. No.: 13/671,438

(22) Filed: Nov. 7, 2012

(30) Foreign Application Priority Data
Nov. 15, 2011 (JP) 2011-249249

(51) Int. Cl. G11C 7/00

(52) U.S. Cl. CPC G11C 7/00
USPC 365/189.15

(57) ABSTRACT

Disclosed herein is a device that includes a first semiconductor chip outputting a read command and a clock signal, a plurality of second semiconductor chips stacked to the first semiconductor chip, and a signal path electrically connected between the first and second semiconductor chips. Each of the second semiconductor chips performs a read operation to read out a data signal stored therein in response to the read command. Each of the second semiconductor chips includes a counter circuit performing a count operation in response to the clock signal to generate a count signal, and an output control circuit outputs the data signal to the signal path when the count signal indicates a predetermined value. The predetermined values of the second semiconductor chips are different from one another.

### BACKGROUND OF THE INVENTION

1. Field of the Invention

The present invention relates to a semiconductor device, and particularly to a semiconductor device equipped with a plurality of core chips.

2. Description of Related Art

In recent years, most electrical products include semiconductor devices. The storage capacity of DRAM (Dynamic Random Access Memory), which functions as a storage device, has been increasing year after year to realize a variety of functions. In order to meet such a demand without an increase in the size of a package of the storage device, a memory device called a multi-chip package has been proposed in recent years: in the multi-chip package, a plurality of memory chips are stacked.

The multi-chip package is slightly larger in size in a thickness direction (vertical direction) because the chips are stacked. However, the size of the package remains unchanged in a lateral direction (horizontal direction). Thus, the more the number of stacked chips increases, the more its capacity increases.

The following multi-chip package is drawing attention: a multi-chip package in which an interface chip, which includes a so-called frontend portion to function as an interface with the outside (a memory controller, for example), and a plurality of core chips, which are a memory core, are stacked.

In such a semiconductor device using an interface chip, the adjacent chips are electrically connected to each other through a large number of through silicon vias (Penetrating Electrodes), which penetrate a substrate of the core chips. Most of the through silicon vias are short-circuited with through silicon vias of other layers, which are provided at the same positions in planar view when seen from a direction in which the chips are stacked. A group of through silicon vias that are electrically short-circuited forms a current path that connects the interface chip to each core chip.

When data are input or output, the selection of a core chip is carried out based on chip selection information, which is supplied from the interface chip to each core chip. Each core chip compares the chip selection information with chip identification information which is allocated in advance. If the chip selection information matches the chip identification information, an input and output operation is carried out. An example of the operation is disclosed in Japanese Patent Application Laid-open No. 2007-157266.

In a semiconductor device of a type that uses the interface chip, sometimes the interface chip need treat data having a larger data width than a data width of each core chip. The followings describe two methods to realize inputting and outputting data in such a case with an example in which the ×16(16DQ) data are read from four core chips whose DQ is ×4 (4DQ) to the interface chip in a semiconductor device using through silicon vias.

In the first method, current paths for inputting and outputting data (which is a current path containing through silicon vias, and is referred to as a “data current path,” hereinafter) are provided for each core chip. The data current paths for one core chip are worth 4DQ and independent from the data current paths for the other core chips. According to the method, the collision of read data does not occur between the core chips. Thus, it is possible to simultaneously read the read data from a plurality of core chips. However, according to the above method, the data current paths that are worth 16DQ, i.e. sixteen data current paths, are required, leading to an increase in the space occupied and resulting in a decrease in the strength of core chips and an increase in the size of chips.

In the second method, common data current paths are shared by each core chip, and the read data are retrieved in a serial manner from each core chip. More specifically, four data current paths are shared by four core chips. The interface chip outputs commands four times to the core chips, and separately receives four sets of the ×4 data that are output from each of the core chips, thereby acquiring the ×16 data. However, the second method has problems as follows: the commands need be output four times; and the control process becomes complex and the operating speed decreases because a temporal gap of several clocks (overhead) occurs during a period of time from when a given core chip outputs the read data until the next core chip outputs the read data.

Even as any one of the above methods is used, an increase in the number of chips stacked compounds the problems. That is, in the case of the first method, the data current paths further increase in number, thereby leading to a further increase in the space occupied by the current paths. In the case of the second method, overheads increases depending on the number of chips stacked, resulting in a further decline in the operating speed.

### SUMMARY

In one embodiment, there is provided a semiconductor device that includes: an interface chip; and a plurality of core chips stacked to the interface chip, the core chips having different chip identification information from one another, at least one of the core chips including a penetration electrode that penetrates therethrough, the penetration electrode forming a part of a data signal path that electrically connects the interface chip to the core chips in common. The interface chip includes a command decoder simultaneously supplying a read command to the core chips. Each of the core chips includes: a memory cell array having a plurality of memory cells; a chip identification information storage unit storing the chip identification information assigned thereto; and a first output circuit reading a read data from the memory cell array in response to the read command, the first output circuit outputting the read data to the interface chip via the data signal path at a timing corresponding to the chip identification information that is stored in the chip identification information storage unit.

In another embodiment, there is provided a semiconductor device that includes: an interface chip; and a plurality of core chips stacked to the interface chip, the core chips having different chip identification information from one another, at least one of the core chips including a plurality of penetration electrodes that penetrate therethrough, the penetration electrodes forming a part of a plurality of data signal paths each of which electrically connects the interface chip to the core chips in common. The interface chip includes a command decoder simultaneously supplying a read command to the core chips. Each of the core chips includes: a memory cell array having a plurality of memory cells; a chip identification information storage unit storing the chip identification information assigned thereto; and a first output circuit reading a plurality of read data from the memory cell array in response to the read command, the first output circuit outputting the plurality of read data to the interface chip via the data signal paths at a timing corresponding to the chip identification information that is stored in the chip identification information storage unit.

In still another embodiment, there is provided a semiconductor device that includes: a first semiconductor chip outputting a read command and a clock signal; a plurality of second semiconductor chips stacked to the first semiconductor chip, each of the second semiconductor chips performing a read operation to read out a data signal stored therein in response to the read command; and a signal path electrically connected between the first and second semiconductor chips. Each of the second semiconductor chips includes: a counter circuit performing a count operation in response to the clock signal to generate a count signal; and an output control circuit outputs the data signal to the signal path when the count signal indicates a predetermined value. The predetermined values of the second semiconductor chips are different from one another.

### BRIEF DESCRIPTION OF THE DRAWINGS

FIG. 1 is a schematic cross-sectional view illustrating the configuration of a semiconductor device according to a preferred embodiment of the present invention;

FIGS. 2A to 2C are diagram showing the various types of through silicon vias TSV provided in a core chip;

FIG. 3 is a cross-sectional view showing the configuration of the through silicon via TSV1 of a type shown in FIG. 2A;

FIG. 4 is a block diagram showing the circuit configuration of the semiconductor device 10 shown in FIG. 1;

FIG. 5 is a schematic block diagram showing a portion (first output circuit) related to simultaneous outputting of the internal structure of a data control circuit 54 shown in FIG. 4;

FIG. 6A is a circuit diagram of a counter 101 shown in FIG. 5;

FIG. 6B is a timing chart of signals related to the counter 101 shown in FIG. 6A;

FIG. 7A is a circuit diagram of a shift register 102 shown in FIG. 5;

FIG. 7B is a timing chart of signals related to the shift register 102 shown in FIG. 7A;

FIG. 8A is a circuit diagram of a shift register 103 shown in FIG. 5;

FIG. 8B is a timing chart of signals related to the shift register 103 shown in FIG. 8A;

FIG. 9 is a circuit diagram of a decoder 104 shown in FIG. 5;

FIG. 10 is a circuit diagram of a multiplexer 105 shown in FIG. 5;

FIG. 11A is a circuit diagram of AND operation circuit 106 shown in FIG. 5;

FIG. 11B is a circuit diagram of AND operation circuit 107 shown in FIG. 5;

FIG. 12 is a timing chart of input timing indication signals DSELIT<3:0> shown in FIG. 11A, output timing indication signals DSELOT<3:0> shown in FIG. 11B, and related signals;

FIG. 13 is a circuit diagram of FIFO 108 shown in FIG. 5; and

FIG. 14 is a timing chart of data DATA_IN shown in FIG. 5, which are supplied from a column decoder 52 to the FIFO 108, data DATA_OUT shown in FIG. 5, which are output from the FIFO 108, and related signals.

### DETAILED DESCRIPTION OF THE EMBODIMENTS

Preferred embodiments of the present invention will be explained below in detail with reference to the accompanying drawings.

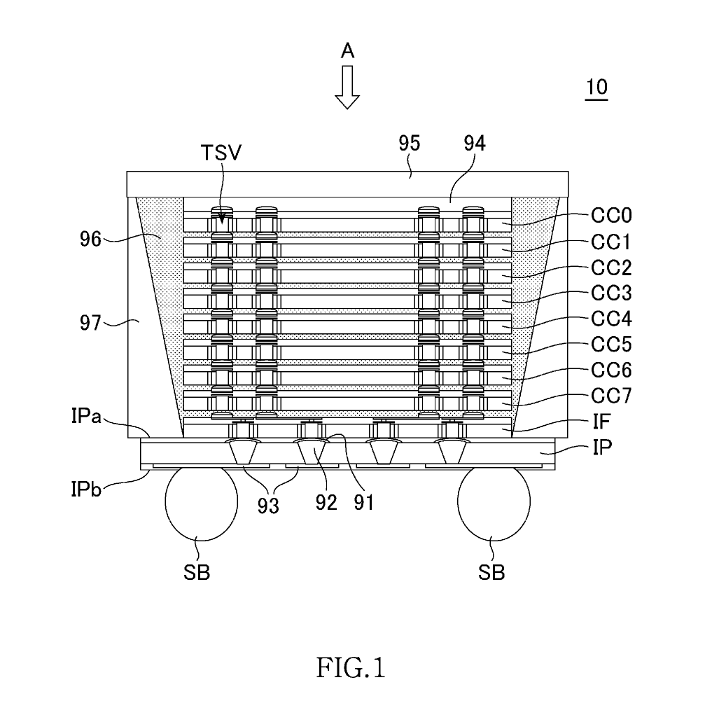

Referring now to FIG. 1, the semiconductor device 10 according to this embodiment has the structure where eight core chips (memory chips) CC0 to CC7 and an interface chip IF are stacked on an interposer IP. The core chips CC0 to CC7 have the same function and structure as one another. It is worth noting that the uppermost core chip CC0 may have a different structure from the other core chips CC1 to CC7. For example, the uppermost core chip CC0 may be thicker than the remaining core chips CC1 to CC7. The core chips CC0 to CC7 are manufactured using the same manufacture mask whereas the interface chip IF is manufactured using a manufacture mask different from that of the core chips CC0 to CC7. The core chips CC0 to CC7 and the interface chip IF are semiconductor chips using a silicon substrate and are electrically connected to adjacent chips in a vertical direction through plural Through Silicon Vias (TSV) penetrating the silicon substrate. The through silicon via may be referred to as a penetration electrode. The uppermost core chip CC0 may not have the through silicon via TSV. Meanwhile, the interposer IP is a circuit board that is made of a resin, and plural external terminals (solder balls) SB are formed in a back surface IPb of the interposer IP.

A well-known and common 1Gb DDR3 (Double Data Rate 3) type of SDRAM (Synchronous Dynamic Random Access Memory), which is a normal memory chip, includes a frontend unit and a backend unit, operates as a single chip, and are so formed as to be able to communicate directly with a memory controller. The front end unit has a function of serving as an interface for the outside via an external terminal. The backend unit includes a plurality of storage cells, and has a function of accessing the storage cells. Each of the core chips CC0 to CC7 is a semiconductor chip that lacks a unit corresponding to the frontend unit (frontend function) among the circuit blocks that such a normal memory chip contains. In other words, each of the core chips CC0 to CC7 is a semiconductor chip where only the circuit blocks belonging to the back end unit are integrated in principle. As examples of the circuit blocks included in the front end unit, a parallel-serial converting circuit (data latch circuit) that performs parallel/serial conversion on input/output data between a memory cell array and a data input/output terminal and a DLL (Delay Locked Loop) circuit that controls input/output timing of data are exemplified. As an example of the circuit blocks included in the backend unit, a memory cell array in which information is stored is exemplified. Since the frontend unit has been removed, the integration degree of the core chips are higher than the storage integration degree of a typical single chip.

The interface chip IF is a semiconductor chip in which only the front end unit is integrated. Accordingly, an operation frequency of the interface chip is higher than that of the core chip. Since the circuits that belong to the front end unit are not included in the core chips CC0 to CC7, the core chips CC0 to CC7 cannot be operated as the single chips, except for the operation for a wafer test conducted in the course of manufacturing the core chips. The interface chip IF is needed to operate the core chips CC0 to CC7.

The interface chip has a front end function for communicating with the external device at a first operation frequency, and each of the core chips cc0 to cc7 has a back end function for communicating with only the interface chip IF at a second operation frequency lower than the first operation frequency. A bit number of read data for each I/O (DQ) that are supplied from the core chips CC0 to CC7 to the interface chip IF in parallel is associated with a one-time read command provided from the interface chip to the core chips. In this case, the bit number of read data corresponds to a prefetch data number to be well-known.

The interface chip IF functions as a common front end unit (a processing circuit processing signals to communicate with the eight core chips CC0 to CC7 and a processing circuit processing signals from/to the external.) for the eight core chips CC0 to CC7. All the communication of the semiconductor device 10 with an external device is carried out via the interface chip IF. Needless to say, the inputting and outputting of data is also carried out via the interface chip IF.

As shown in FIG. 1, according to the present embodiment, the interface chip IF is disposed between the interposer IP and the core chips CC0 to CC7. However, the position of the interface chip IF is not limited to the above position. The interface chip IF may be disposed above the core chips CC0 to CC7, or on the back surface IPb of the interposer IP. If the interface chip IF is disposed on an upper portion of the core chips CC0 to CC7 face down, or if the interface chip IF is disposed on the back surface IPb of the interposer IP face up, there is no need to provide through silicon vias TSV in the interface chip IF. The interface chip IF may be so disposed as to be sandwiched between two interposers IP.

The interposer IP functions as a rewiring substrate to increase an electrode pitch and secures mechanical strength of the semiconductor memory device 10. That is, an electrode 91 that is formed on a top surface IPa of the interposer IP is drawn to the back surface IPb via a through-hole electrode 92 and the pitch of the external terminals SB is enlarged by the rewiring layer 93 provided on the back surface IPb. In FIG. 1, only the two external terminals SB are shown. In actuality, however, a lot of external terminals are provided. The layout of the external terminals SB is the same as that of the DDR3-type SDRAM that is determined by the regulation. Accordingly, the semiconductor memory device can be treated as one DDR3-type SDRAM from the external controller.

As shown in FIG. 1, a top surface of the uppermost core chip CC0 is covered by an NCF (Non-Conductive Film) 94 and a lead frame 95. Gaps between the core chips CC0 to CC7 and the interface chip IF are filled with an underfill 96 and surrounding portions of the gaps are covered by a sealing resin 97. Thereby, the individual chips are physically protected.

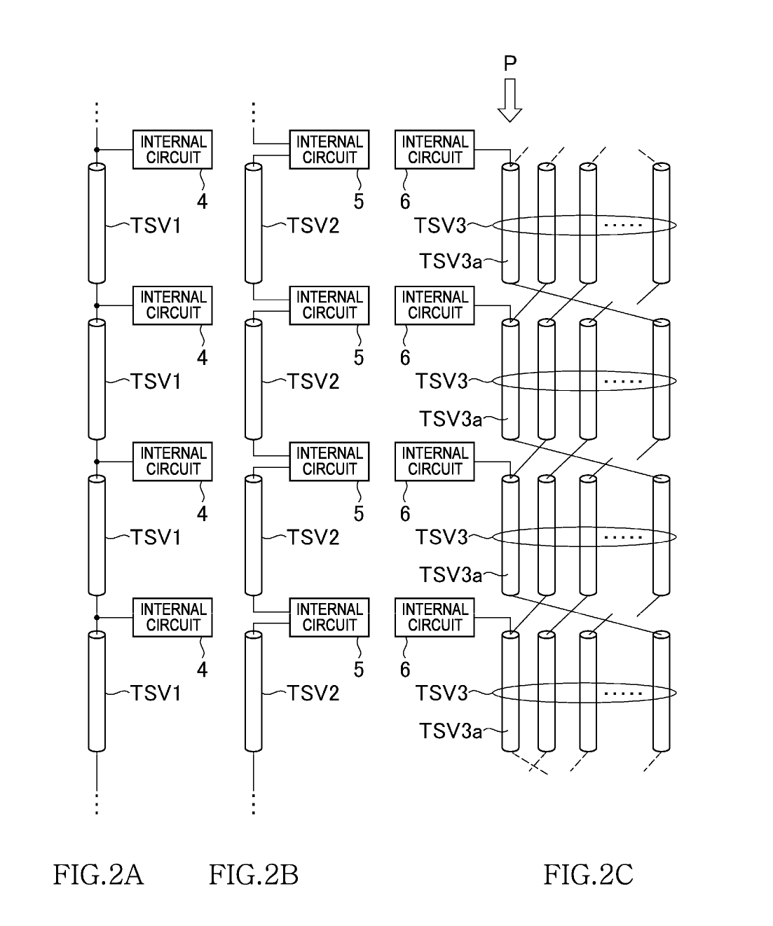

Most of the through silicon vias TSV provided in the core chips CC0 to CC7 are short-circuited from the through silicon vias TSV of other layers provided at the same position when two-dimensionally viewed from a lamination direction, that is, viewed from an arrow A shown in FIG. 1. That is, as shown in FIG. 2A, the vertically disposed through silicon vias TSV1 that are provided at the same position in plan view are short-circuited, and one current path is configured by the through silicon vias TSV1. The through silicon vias TSV1 that are provided in the core chips CC0 to CC7 are connected to internal circuits 4 in the core chips, respectively. Accordingly, input signals (command signal, address signal, etc.) that are supplied from the interface chip IF to the through silicon vias TSV1 shown in FIG. 2A are commonly input to the internal circuits 4 of the core chips CC0 to CC7. Output signals (data etc.) that are supplied from the core chips CC0 to CC7 to the through silicon vias TSV1 are wired-ORed and input to the interface chip IF.

Meanwhile, as shown in FIG. 2B, a part of through silicon vias TSV are not directly connected to the through silicon via TSV2 of other layers provided at the same position in plain view but are connected to the through silicon via TSV2 of other layers through the internal circuits 5 provided in the core chips CC0 to CC7. That is, the internal circuits 5 that are provided in the core chips CC0 to CC7 are cascade-connected through the through silicon vias TSV2 and the current path configured by the through silicon vias TSV2 includes the internal circuits 5. This kind of through silicon vias TSV2 is used to sequentially transmit predetermined information to the internal circuits 5 provided in the core chips CC0 to CC7. As this information, layer address information to be described below is exemplified.

Another through silicon via TSV group is short-circuited from the through silicon via TSVs of other layer provided at the different position in plan view, as shown in FIG. 2C. With respect to this kind of through silicon via TSV 3, internal circuits 6 of the core chips CC0 to CC7 are connected to the through silicon via TSV3a provided at the predetermined position P in plan view. Each of the current paths configured by the through silicon vias TSV3 is connected to the internal circuit 6 provided in only one of the core chips, respectively. Thereby, information can be selectively input to the internal circuit 6 provided in each of the core chips. As this information, defective chip information described below is exemplified.

As such, as types of the through silicon vias TSV provided in the core chips CC0 to CC7, three types (through silicon vias TSV1 to through silicon vias TSV3) shown in FIGS. 2A to 2C exist. As described above, most of the through silicon vias TSV are of a type shown in FIG. 2A, and an address signal, a command signal, and a clock signal are supplied from the interface chip IF to the core chips CC0 to CC7, through the through silicon vias TSV1 of the type shown in FIG. 2A. Read data and write data are also input to and output from the interface chip IF through the through silicon vias TSV1 of the type shown in FIG. 2A. Meanwhile, the through silicon vias TSV2 and through silicon vias TSV3 of the types shown in FIGS. 2B and 2C are used to provide individual information to the core chips CC0 to CC7 having the same structure.

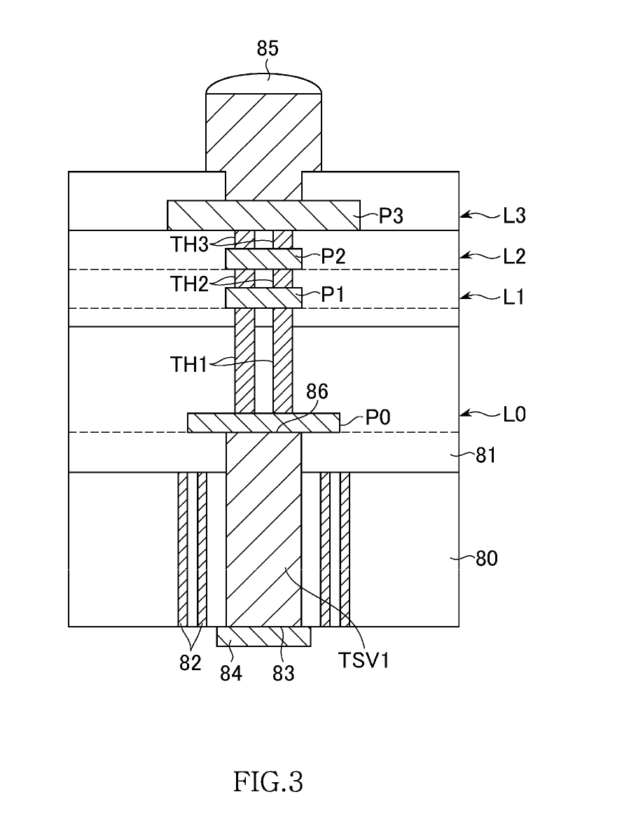

Turning to FIG. 3, the through silicon via TSV1 is provided to penetrate a silicon substrate 80 and an interlayer insulating film 81 provided on a surface of the silicon substrate 80. Around the through silicon via TSV1, an insulating ring 82 is provided. Thereby, the through silicon via TSV1 and a transistor region are insulated from each other. In an example shown in FIG. 3, the insulating ring 82 is provided double. Thereby, capacitance between the through silicon via TSV1 and the silicon substrate 80 is reduced.

An end 83 of the through silicon via TSV1 at the back surface of the silicon substrate 80 is covered by a back surface bump 84. The back surface bump 84 is an electrode that contacts a surface bump 85 provided in a core chip of a lower layer. The surface bump 85 is connected to an end 86 of the through silicon via TSV1, through plural pads P0 to P3 provided in wiring layers L0 to L3 and plural through-hole electrodes TH1 to TH3 connecting the pads to each other. Thereby, the surface bump 85 and the back surface bump 84 that are provided at the same position in plan view are short-circuited. Connection with internal circuits (not shown in the drawings) is performed through internal wiring lines (not shown in the drawings) drawn from the pads P0 to P3 provided in the wiring layers L0 to L3.

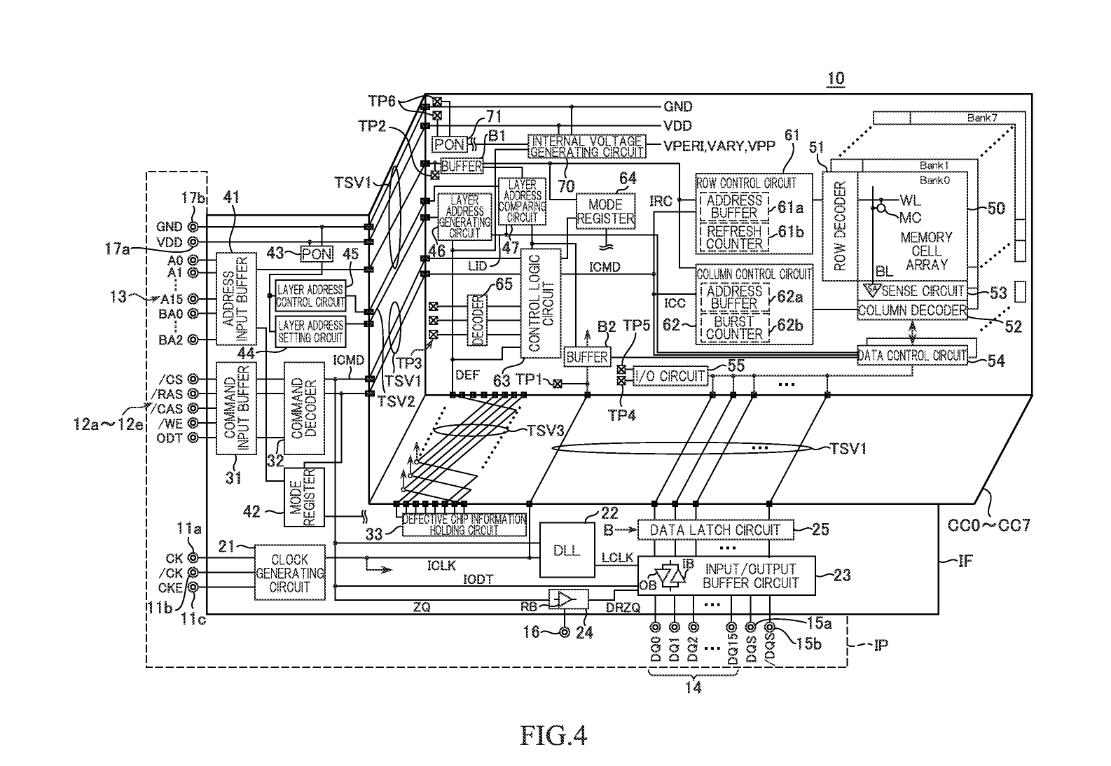

Turning to FIG. 4, the external terminals that are provided in the interposer IP include clock terminals 11a and 11b, an clock enable terminal 11c, command terminals 12a to 12e, an address terminal 13, a data input/output terminal 14, data strobe terminals 15a and 15b, a calibration terminal 16, and power supply terminals 17a and 17b. All of the external terminals are connected to the interface chip IF and are not directly connected to the core chips CC0 to CC7, except for the power supply terminals 17a and 17b.

First, a connection relationship between the external terminals and the interface chip IF performing the front end function and the circuit configuration of the interface chip IF will be described.

The clock terminals 11a and 11b are supplied with external clock signals CK and /CK, respectively, and the clock enable terminal 11c is supplied with a clock enable signal CKE. The external clock signals CK and /CK and the clock enable signal CKE are supplied to a clock generating circuit 21 provided in the interface chip IF. A signal where “/” is added to a head of a signal name in this specification indicates an inversion signal of a corresponding signal or a low-active signal. Accordingly, the external clock signals CK and /CK are complementary signals. The clock generating circuit 21 generates an internal clock signal ICLK, and the generated internal clock signal ICLK is supplied to various circuit blocks in the interface chip IF and is commonly supplied to the core chips CC0 to CC7 through the through silicon vias TSV.

Moreover, the interface chip IF includes a DLL circuit 22. The DLL circuit 22 includes a replica circuit of the input/output buffer circuit 23. The DLL circuit 22 generates an input/output clock signal LCLK using the replica circuit. More specifically, the DLL circuit 22 supplies the generated input/output clock signal LCLK to the replica circuit, and adjusts the phase and duty of the input/output clock signal LCLK in such a way that the signals that are eventually output from the replica circuit are in synchronization with the external clock signals CK and /CK. The input/output clock signal LCLK generated by the DLL circuit 22 is supplied to the input/output buffer circuit 23. The input/output buffer circuit 23 outputs the read data in synchronization with the input/output clock signal LCLK. The reason why the DLL circuit 22 is provided in the interface chip IF is because, when the semiconductor device 10 outputs the read data to the outside, the output timing needs to be in synchronization with the external clock signals CK and /CK. The function of outputting the read data to the outside belongs to the frontend function. Accordingly, the DLL function is unnecessary for the core chips CC0 to CC7, which are the backend unit.

The command terminals 12a to 12e are supplied with a row-address strobe signal /RAS, a column address strobe signal /CAS, a write enable signal /WE, a chip select signal /CS, and an on-die termination signal ODT. These command signals are supplied to a command input buffer 31 that is provided in the interface chip IF. The command signals supplied to the command input buffer 31 are further supplied to a command decoder 32. The command decoder 32 generates various internal commands ICMD by holding, decoding, and counting the command signals in synchronization with the internal clock ICLK. The generated internal command ICMD is supplied to the various circuit blocks in the interface chip IF and is commonly supplied to the core chips CC0 to CC7 through the through silicon vias TSV1 of a type shown in FIG. 2(a).

The address terminal 13 is a terminal to which address signals A0 to A15 and BA0 to BA2 are supplied, and the supplied address signals A0 to A15 and BA0 to BA2 are supplied to an address input buffer 41 provided in the interface chip IF. An output of the address input buffer 41 is commonly supplied to the core chips CC0 to CC7 through the through silicon vias TSV 1 of a type shown in FIG. 2(a). The address signals A0 to A15 are supplied to a mode register 42 provided in the interface chip IF, when the semiconductor memory device 10 enters a mode register set. The address signals BA0 to BA2 (bank addresses) are decoded by an address decoder (not shown in the drawings) provided in the interface chip IF, and a bank selection signal B that is obtained by the decoding is supplied to a data latch circuit 25. This is because bank selection of the write data is performed in the interface chip IF.

The data input/output terminal 14 is a terminal that is used to input/output read data or write data DQ0 to DQ15. The data strobe terminals 15a and 15b are terminals that are used to input/output strobe signals DQS and /DQS. The data input/output terminal 14 and the data strobe terminals 15a and 15b are connected to the input/output buffer circuit 23 provided in the interface chip IF. The input/output buffer circuit 23 includes an input buffer IB and an output buffer OB, and inputs/outputs the read data or the write data DQ0 to DQ15 and the strobe signals DQS and /DQS in synchronization with the input/output clock signal LCLK supplied from the DLL circuit 22. If an internal on-die termination signal IODT is supplied from the command decoder 32, the input/output buffer circuit 23 causes the output buffer OB to function as a termination resistor. An impedance code DRZQ is supplied from the calibration circuit 24 to the input/output buffer circuit 23. Thereby, impedance of the output buffer OB is designated. The input/output buffer circuit 23 includes a well-known FIFO circuit.

The calibration circuit 24 includes a replica buffer RB that has the same circuit configuration as the output buffer OB. When the calibration signal ZQ is supplied from the command decoder 32, the calibration circuit 24 performs a calibration operation by referring to a resistance value of an external resistor (not shown in the drawings) connected to the calibration terminal 16. The calibration operation is an operation for matching the impedance of the replica buffer RB with the resistance value of the external resistor, and the obtained impedance code DRZQ is supplied to the input/output buffer circuit 23. Thereby, the impedance of the output buffer OB is adjusted to a desired value.

The input/output buffer circuit 23 is connected to a data latch circuit 25. The data latch circuit 25 includes a FIFO circuit (not shown in the drawings) that realizes a FIFO function which operates by latency control realizing the well-known DDR function and a multiplexer MUX (not shown in the drawings). The input/output buffer circuit 23 converts parallel read data, which is supplied from the core chips CC0 to CC7, into serial read data, and converts serial write data, which is supplied from the input/output buffer, into parallel write data. Accordingly, the data latch circuit 25 and the input/output buffer circuit 23 are connected in serial and the data latch circuit 25 and the core chips CC0 to CC7 are connected in parallel. The data latch circuit 25 and the core chips CC0 to CC7 are connected for each bank. Therefore, assuming that the number of the banks included in each of the core chips CC0 to CC7 is 8 and the prefetch number is 8 bits, the number of connections between the data latch circuit 25 and the core chips CC0 to CC7 becomes 64 bits (=8 bits×8 banks) for each data input/output terminal 14. This connection is realized by providing 64 current paths (data current paths) containing the through silicon vias TSV1 of a type shown in FIG. 2A. Therefore, for example, if the number of data input/output terminals 14 provided is 16, the total number of the data current paths is 1,024 (=64×16). All the data current paths, the number of which is 1,024, are shared by the core chips CC0 to CC7.

As mentioned above, parallel data, not converted into serial data, is basically transferred between the data latch circuit 25 and the core chips CC0 to CC7. That is, in a common SDRAM (in which a front end unit and a back end unit are constructed in one chip), between the outside of the chip and the SDRAM, data is input/output in serial (that is, the number of data input/output terminals is one for each DQ). However, in the core chips CC0 to CC7, an input/output of data between the interface chip IF and the core chips is performed in parallel. This point is the important difference between the common SDRAM and the core chips CC0 to CC7. However, all of the prefetched parallel data do not need to be input/output using the different through silicon vias TSV, and the number of through silicon vias TSV that are needed for each DQ may be reduced by implementing partial parallel/serial conversion in the core chips CC0 to CC7. For example, all of data of 64 bits for each DQ do not need to be input/output using the different through silicon vias TSV, and the number of through silicon vias TSV1 that are needed for each data input/output terminal 14 may be reduced to ½ (32) by implementing 2-bit parallel/serial conversion in the core chips CC0 to CC7.

Further, to the data latch circuit 25, a function for enabling a test in an interface chip unit is added. The interface chip does not have the back end unit. For this reason, the interface chip cannot be operated as a single chip in principle. However, if the interface chip never operates as the single chip, an operation test of the interface chip in a wafer state may not be performed. This means that the semiconductor memory device 10 cannot be tested in case an assembly process of the interface chip and the plural core chips is not executed, and the interface chip is tested by testing the semiconductor memory device 10. In this case, when a defect that cannot be recovered exists in the interface chip, the entire semiconductor memory device 10 is not available. In consideration of this point, in this embodiment, a pseudo unit of a portion of a back end unit for a test is provided in the data latch circuit 25, and a simple memory function is enabled at the time of a test.

The power supply terminals 17a and 17b are terminals to which power supply potentials VDD and VSS are supplied, respectively. The power supply terminals 17a and 17b are connected to a power-on detecting circuit 43 provided in the interface chip IF and are also connected to the core chips CC0 to CC7 through the through silicon vias TSV. The power-on detecting circuit 43 detects the supply of power. On detecting the supply of power, the power-on detecting circuit 43 activates a layer address control circuit 45 provided in the interface chip IF.

The layer address control circuit 45 changes a layer address due to the I/O configuration of the semiconductor device 10 according to the present embodiment. As described above, the semiconductor memory device 10 includes 16 data input/output terminals 14. Thereby, a maximum I/O number can be set to 16 bits (DQ0 to DQ15). However, the I/O number is not fixed to 16 bits and may be set to 8 bits (DQ0 to DQ7) or 4 bits (DQ0 to DQ3). The address allocation is changed according to the I/O number and the layer address is also changed according to the I/O number. The layer address control circuit 45 controls changing the address allocation according to the I/O number and is commonly connected to the core chips CC0 to CC7 through the through silicon vias TSV.

The interface chip IF is also provided with a layer address setting circuit 44. The layer address setting circuit 44 is connected to the core chips CC0 to CC7 through the through silicon vias TSV. The layer address setting circuit 44 is cascade-connected to the layer address generating circuit 46 of the core chips CC0 to CC7 using the through silicon via TSV2 of the type shown in FIG. 2B, and reads out the layer addresses set to the core chips CC0 to CC7 at testing.

The interface chip IF is also provided with a defective chip information holding circuit 33. When a defective core chip that does not normally operates is discovered after an assembly, the defective chip information holding circuit 33 holds its chip number. The defective chip information holding circuit 33 is connected to the core chips CC0 to CC7 through the through silicon vias TSV. The defective chip information holding circuit 33 is connected to the core chips CC0 to CC7 while being shifted, using the through silicon via TSV3 of the type shown in FIG. 2C.

The above description is the outline of the connection relationship between the external terminals and the interface chip IF and the circuit configuration of the interface chip IF. Next, the circuit configuration of the core chips CC0 to CC7 will be described.

As shown in FIG. 4, memory cell arrays 50 that are included in the core chips CC0 to CC7 and performs the back end function are divided into eight banks. A bank is a unit that can individually receive a command. That is, the individual banks can be independently and nonexclusively controlled. From the outside of the semiconductor memory device 10, each back can be independently accessed. For example, a part of the memory cell array 50 belonging to the bank 1 and another part of the memory cell array 50 belonging to the bank 2 are controlled nonexclusively. That is, word lines WL and bit lines BL corresponding to each banks respectively are independently accessed at same period by different commands one another. For example, while the bank 1 is maintained to be active (the word lines and the bit lines are controlled to be active), the bank 2 can be controlled to be active.

In the memory cell array 50, the plural word lines WL and the plural bit lines BL intersect each other, and memory cells MC are disposed at intersections thereof (in FIG. 4, only one word line WL, one bit line BL, and one memory cell MC are shown). The word line WL is selected by a row decoder 51. The bit line BL is connected to a corresponding sense amplifier SA in a sense circuit 53. The sense amplifier SA is selected by a column decoder 52.

The row decoder 51 is controlled by a row address supplied from a row control circuit 61. The row control circuit 61 includes an address buffer 61a that receives a row address supplied from the interface chip IF through the through silicon via TSV, and the row address that is buffered by the address buffer 61a is supplied to the row decoder 51. The address signal that is supplied through the through silicon via TSV is supplied to the row control circuit 61 through the input buffer B1. The row control circuit 61 also includes a refresh counter 61b. When a refresh signal is issued by a control logic circuit 63, a row address that is indicated by the refresh counter 61b is supplied to the row decoder 51.

The column decoder 52 is controlled by a column address supplied from a column control circuit 62. The column control circuit 62 includes an address buffer 62a that receives the column address supplied from the interface chip IF through the through silicon via TSV, and the column address that is buffered by the address buffer 62a is supplied to the column decoder 52. The column control circuit 62 also includes a burst counter 62b that counts the burst length.

The sense amplifier SA selected by the column decoder 52 is connected to the data control circuit 54 through some amplifiers (sub-amplifiers or data amplifiers, for example) which are not shown in the drawings. Thereby, read data of 8 bits (=prefetch number) for each I/O (DQ) is output from the data control circuit 54 at reading, and write data of 8 bits is input to the data control circuit 54 at writing. The data control circuit 54 and the interface chip IF are connected in parallel through a plural of the through silicon vias TSV which are commonly used between the core chips CC0 to CC7.

The control logic circuit 63 receives an internal command ICMD supplied from the interface chip IF through the through silicon via TSV and controls the row control circuit 61, the column control circuit 62, and the data control circuit 54, based on the internal command ICMD. The control logic circuit 63 is connected to a layer address comparing circuit (chip information comparing circuit) 47. The layer address comparing circuit 47 detects whether the corresponding core chip is target of access, and the detection is performed by comparing a SEL (chip selection information) which is a part of the address signal supplied from the interface chip IF through the through silicon via TSV and a layer address LID (chip identification information) set to the layer address generating circuit 46.

According to the present embodiment, in some cases, the command decoder 32 supplies the read command to the core chips CC0 to CC7 at once. In this case, the outputs of the layer address comparing circuit 47 are data indicating an access target in all the core chips. On receiving the data, the control logic circuit 63 of each core chip simultaneously begins to control the row control circuit 61, the column control circuit 62, and the data control circuit 54. Incidentally, the address signals in this case are common between the core chips CC0 to CC7. Due to the control process, the read data are read in parallel among the core chips CC0 to CC7. However, as described above, because the common data current paths are used by the core chips CC0 to CC7, the collision of the read data would occur if the read data are simultaneously output by the core chips. Accordingly, the data control circuit 54 of the present embodiment outputs the read data to the interface chip IF at a timing corresponding to the layer address LID. As a result, the read data are output from the core chips CC0 to CC7 in a serial manner, or, in other words, in such a way that the outputting periods of the core chips CC0 to CC7 do not overlap with each other, thereby preventing the occurrence of collision. The details will be given later.

The layer address generating circuit 46 is a chip identification information storage unit in which the layer address LID (chip identification information) assigned to the corresponding core chip is stored. The layer addresses LID are data unique to each of the core chips CC0 to CC7. The layer addresses LID that are stored by the core chips CC0 to CC7 are set at the time of the initialization of the semiconductor device 10.

The following describes a method of setting the layer addresses LID. First, as the semiconductor device 10 is initialized, minimum values (0, 0, 0) are set in the layer address generating circuit 46 of each of the core chips CC0 to CC7 as initial values. The layer address generating circuits 46 of the core chips CC0 to CC7 are connected in cascade by means of the through silicon vias TSV2 of a type shown in FIG. 2B. Moreover, the layer address generating circuits 46 contain an increment circuit. The layer address (0, 0, 0) that has been set in the layer address generating circuit 46 of the top-layer core chip CC0 is sent to the layer address generating circuit 46 of the second core chip CC1 via the through silicon vias TSV, and then is incremented. As a result, a different layer address (0, 0, 1) is generated. Similarly, the generated layer addresses are transferred to the lower-layer core chips, and the layer address generating circuits 46 in the destination core chips increment the layer addresses. In the layer address generating circuit 46 of the core chip CC7 of the bottom layer, maximum values (1, 1, 1) are set as a layer address. In this manner, the unique layer address LID is set in each of the core chips CC0 to CC7.

The layer address generating circuit 46 is supplied with a defective chip signal DEF from the defective chip information holding circuit 33 of the interface chip IF, through the through silicon via TSV. As the defective chip signal DEF is supplied to the individual core chips CC0 to CC7 using the through silicon via TSV3 of the type shown in FIG. 2C, the defective chip signals DEF can be supplied to the core chips CC0 to CC7, individually. The defective chip signal DEF is activated when the corresponding core chip is a defective chip. When the defective chip signal DEF is activated, the layer address generating circuit 46 transmits, to the core chip of the lower layer, a non-incremented layer address, not an incremented layer address. The defective chip signal DEF is also supplied to the control logic circuit 63. When the defective chip signal DEF is activated, the control logic circuit 63 is completely halted. Thereby, the defective core chip performs neither read operation nor write operation, even though an address signal or a command signal is input from the interface chip IF.

An output of the control logic circuit 63 is also supplied to a mode register 64. When an output of the control logic circuit 63 shows a mode register set, the mode register 64 is updated by an address signal. Thereby, operation modes of the core chips CC0 to CC7 are set.

Each of the core chips CC0 to CC7 has an internal voltage generating circuit 70. The internal voltage generating circuit 70 is supplied with power supply potentials VDD and VSS. The internal voltage generating circuit 70 receives these power supply potentials and generates various internal voltages. As the internal voltages that are generated by the internal voltage generating circuit 70, an internal voltage VPERI (≈VDD) for operation power of various peripheral circuits, an internal voltage VARY (<VDD) for an array voltage of the memory cell array 50, and an internal voltage VPP (>VDD) for an activation potential of the word line WL are included. In each of the core chips CC0 to CC7, a power-on detecting circuit 71 is also provided. When the supply of power is detected, the power-on detecting circuit 71 resets various internal circuits.

The peripheral circuits in the core chips CC0 to CC7 operates in synchronization with the internal clock signal ICLK that is supplied form the interface chip IF through the through silicon via TSV. The internal clock signal ICLK supplied through the through silicon via TSV is supplied to the various peripheral circuits including the data control circuit 54 through the input buffer B2.

The above description is the basic circuit configuration of the core chips CC0 to CC7. In the core chips CC0 to CC7, the front end unit for an interface with the external device is not provided. Therefore the core chip cannot operate as a single chip in principle. However, if the core chip never operates as the single chip, an operation test of the core chip in a wafer state may not be performed. This means that the semiconductor memory device 10 cannot be tested, before the interface chip and the plural core chips are fully assembled. In other words, the individual core chips are tested when testing the semiconductor memory device 10. When unrecoverable defect exists in the core chips, the entire semiconductor memory device 10 is led to be unavailable. In consideration of this point, in this embodiment, in the core chips CC0 to CC7, some test pads TP and a pseudo unit of a portion of a front end unit for a test configured by a test front end unit of a test command decoder 65 are provided, and an address signal, a test data, or a command signal can be input from the test pads TP. It is noted that the test front end unit is provided for a simple test in a wafer test, and does not have all of the front end functions in the interface chip IF. For example, since an operation frequency of the core chips is lower than an operation frequency of the front end unit, the test front end unit can be simply realized with a circuit that performs a test with a low frequency.

The kind of the test pads TP is almost the same as those of the external terminals provided in the interposer IP. Specifically, the test pads TP include a test pad TP1 supplied with the clock signal, a test pad TP2 supplied with the address signal, test pads TP3 supplied with the command signal, a test pad TP4 for performing input/output of test data, a test pad TP5 for performing input/output of data strobe signal, test pads 6 for supplying power-supply voltages.

A common external command (not decoded) is input at testing. Therefore, the test command decoder 65 is also provided in each of the core chips CC0 to CC7. Because serial test data is input and output at testing, a test input/output circuit 55 is also provided in each of the core chips CC0 to CC7.

The above has described the overall configuration of the semiconductor device 10 according to the present embodiment. The following provides a description of the configuration that enables the read data, which are simultaneously read by the core chips CC0 to CC7, to be output in a serial manner from the core chips CC0 to CC7 to the interface chip IF through the common data current paths that are shared by the core chips CC0 to CC7. In the following description, such an output process of read data is referred to as “simultaneous outputting.” Moreover, in the description given below, for ease of explanation, the number of core chips stacked is four; the following description also focuses on the read data that are output via one data current path. Furthermore, in the following description, suppose that each core chip outputs the four-bit read data in a burst mode via one data current path.

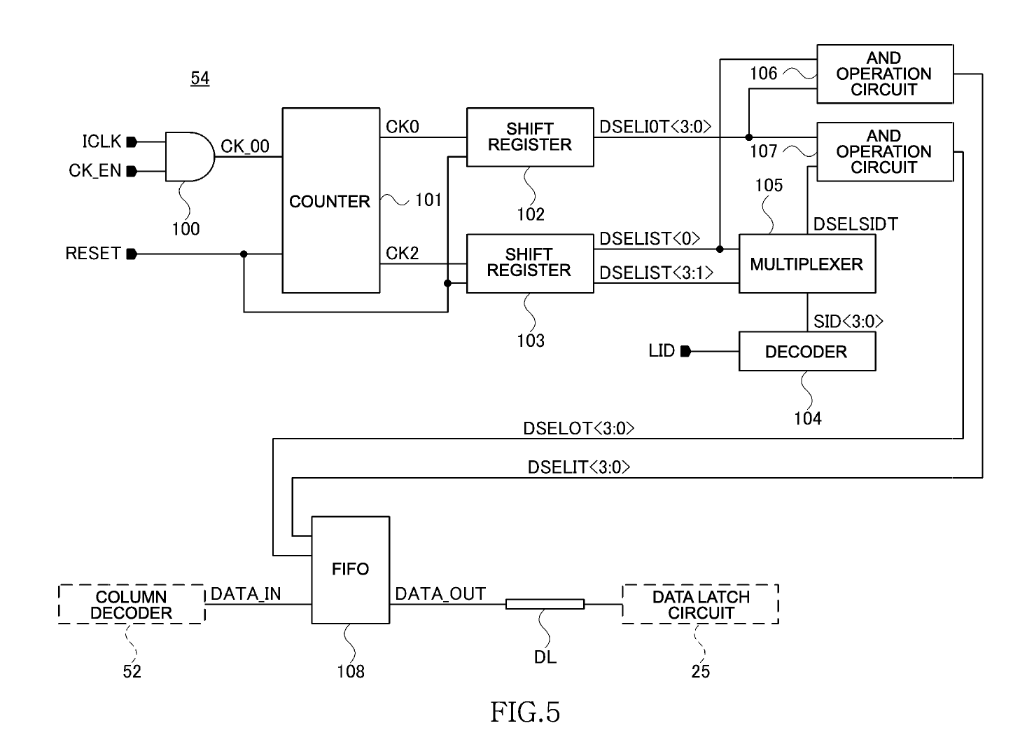

As shown in FIG. 5, the data control circuit 54 includes an AND circuit 100, a counter 101, shift registers 102 and 103, a decoder 104, a multiplexer 105, AND operation circuits 106 and 107, and FIFO (First In First Out) 108.

The AND circuit 100 is a circuit that receives the internal clock signal ICLK and the clock enable signal CK_EN and generates the clock signal CK_00. The clock enable signal CK_EN is a signal that is activated by the control logic circuit 63 shown in FIG. 4 right before simultaneous outputting is carried out; the active state thereof is maintained until simultaneous outputting is completed. Accordingly, the clock signal CK_00 is a signal that is equal to the internal clock signal ICLK only in case the clock enable signal CK_EN is activated; otherwise, the clock signal CK_00 is in an inactive state.

The counter 101 is a circuit that generates the clock signals CK0 and CK2 based on the clock signal CK_00. To the counter 101, the reset signal RESET is also supplied from the control logic circuit 63. The reset signal RESET is a signal that becomes temporarily activated by the control logic circuit 63 shown in FIG. 4 just before simultaneous outputting takes place.

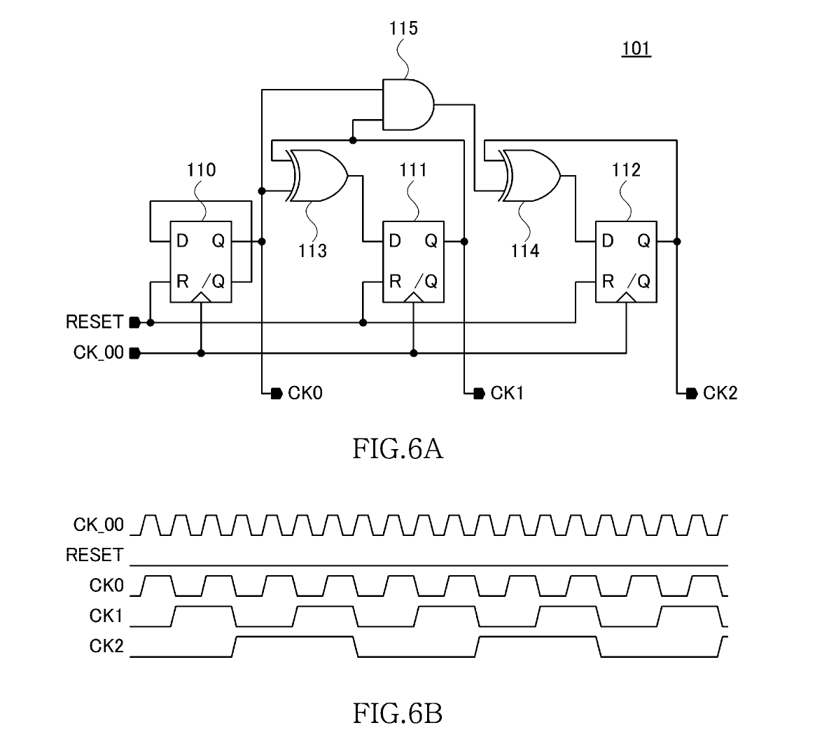

As shown in FIG. 6A, the counter 101 includes D-type flip-flops 110 to 112, exclusive OR circuits 113 and 114, and an AND circuit 115.

The D-type flip-flops 110 to 112 each have an input terminal D, complementary output terminals Q and /Q, a reset terminal R, and a clock terminal. The following provides a brief description of the functions of the D-type flip-flops 110 to 112. First, the output terminals Q and /Q are set to Low and High, respectively, as an input of the reset terminal R is activated. The state is maintained until a rising edge appears at the clock terminal. As a rising edge appears at the clock terminal, the values of the output terminals Q and /Q are changed to an input value of the input terminal D at the time and an inverted value thereof, respectively. The state is maintained until the next rising edge appears at the clock terminal.

To the clock terminals and reset terminals R of the D-type flip-flops 110 to 112, the clock signal CK_00 and the reset signal RESET are respectively supplied. The output terminal /Q and input terminal D of the D-type flip-flop 110 are connected reciprocally. The output terminal Q of the D-type flip-flop 110 is connected to one of the input terminals of the exclusive OR circuit 113, as well as to one of the input terminals of the AND circuit 115. The input terminal D of the D-type flip-flop 111 is connected to the output terminal of the exclusive OR circuit 113. The output terminal Q of the D-type flip-flop 111 is connected to the other input terminal of the exclusive OR circuit 113, as well as to the other input terminal of the AND circuit 115. The input terminal D of the D-type flip-flop 112 is connected to the output terminal of the exclusive OR circuit 114. The output terminal Q of the D-type flip-flop 112 is connected to one of the input terminals of the exclusive OR circuit 114. The output terminal of the AND circuit 115 is connected to the other input terminal of the exclusive OR circuit 114. The signals that appear at the output terminals Q of the D-type flip-flops 110 to 112 become clock signals CK0 to CK2, respectively. Among the clock signals CK0 to CK2, the clock signals CK0 and CK2 become output signals of the counter 101.

As shown in FIG. 6B, the clock signals CK0, CK1, and CK2 turn out to be clock signals whose cycles are two, four, and eight times as long as that of the clock signal CK_00, respectively.

Returning to FIG. 5, the shift register 102 is a circuit that generates the intermediate signals DSELI0T <3:0> based on the clock signal CK0. Incidentally, “DSELI0T <3:0>” means DSELI0T<0> to DSELI0T<3>. The same is applied to other signals described later. Even to the shift register 102, the reset signal RESET is supplied from the control logic circuit 63.

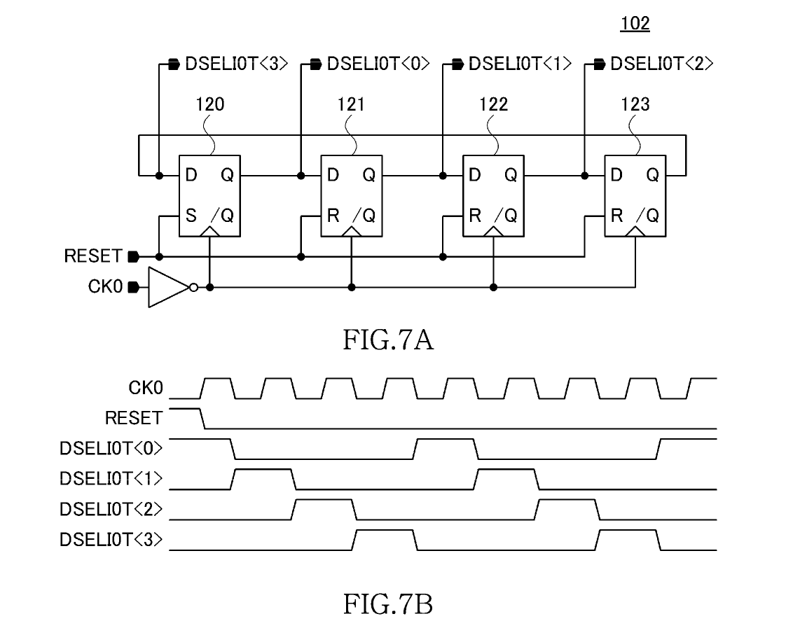

As shown in FIG. 7A, the shift register 102 includes D-type flip-flops 120 to 123. Among the D-type flip-flops 120 to 123, the D-type flip-flops 121 to 123 have the same configuration as the above-mentioned D-type flip-flops 110 to 112. Meanwhile, the D-type flip-flop 120 has a configuration that is realized by replacing the reset terminal R in the above-mentioned D-type flip-flops 110 to 112 with a set terminal S. Accordingly, the output terminals Q and /Q of the D-type flip-flop 120 are set to High and Low, respectively, as an input of the set terminal R becomes activated.

To the clock terminals of the D-type flip-flops 120 to 123, an inverted signal of the clock signal CK0 is supplied. To the set terminal of the D-type flip-flop 120 and to the reset terminals of the D-type flip-flops 121 to 123, the reset signal RESET is supplied. Moreover, the input terminal D of the D-type flip-flop 120 is connected to the output terminal Q of the D-type flip-flop 123, the input terminal D of the D-type flip-flop 121 to the output terminal Q of the D-type flip-flop 120, the input terminal D of the D-type flip-flop 122 to the output terminal Q of the D-type flip-flop 121, and the input terminal D of the D-type flip-flop 123 to the output terminal Q of the D-type flip-flop 122. The intermediate signals DSELI0T <0> to DSELI0T <3> are respectively taken out from the output terminals Q of the D-type flip-flops 120 to 123.

As shown in FIG. 7B, during a period of time when the reset signal RESET is activated, the intermediate signal DSELI0T <0> is activated. As the reset signal RESET returns to an inactive state, the intermediate signal DSELI0T <0> becomes inactivated at the next falling edge of the clock signal CK0. Instead, the intermediate signal DSELI0T <1> becomes activated. Similarly, each time a falling edge of the clock signal CK0 appears, the intermediate signals are sequentially and repeatedly activated in the following order: the intermediate signal DSELI0T <2>, the intermediate signal DSELI0T <3>, the intermediate signal DSELI0T <0>, . . . . The active period of each signal is equal in length to one cycle of the clock signal CK0, which is equivalent to two cycles of the clock signal CK_00.

Returning to FIG. 5, the shift register 103 is a circuit that generates the intermediate signals DSELIST <3:0> based on the clock signal CK2. Even to the shift register 103, the reset signal RESET is supplied from the control logic circuit 63.

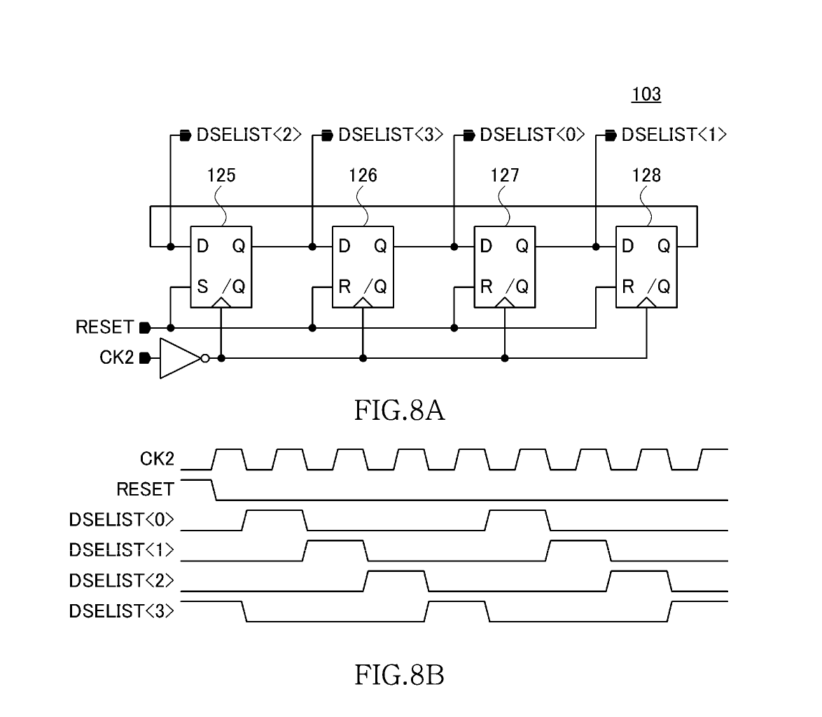

As shown in FIG. 8A, the shift register 103 includes D-type flip-flops 125 to 128. Among the D-type flip-flops 125 to 128, the D-type flip-flop 125 has the same configuration as the above-mentioned D-type flip-flop 120. The D-type flip-flops 126 to 128 have the same configuration as the above-mentioned D-type flip-flops 121 to 123.

To the clock terminals of the D-type flip-flops 125 to 128, an inverted signal of the clock signal CK2 is supplied. To the set terminal of the D-type flip-flop 125 and to the reset terminals of the D-type flip-flops 126 to 128, the reset signal RESET is supplied. Moreover, the input terminal D of the D-type flip-flop 125 is connected to the output terminal Q of the D-type flip-flop 128, the input terminal D of the D-type flip-flop 126 to the output terminal Q of the D-type flip-flop 125, the input terminal D of the D-type flip-flop 127 to the output terminal Q of the D-type flip-flop 126, and the input terminal D of the D-type flip-flop 128 to the output terminal Q of the D-type flip-flop 127. The intermediate signals DSELIST <0> to DSELIST <3> are respectively taken out from the output terminals Q of the D-type flip-flops 126, 127, 128, and 125.

As shown in FIG. 8B, during a period of time when the reset signal RESET is activated, the intermediate signal DSELIST <3> is activated. As the reset signal RESET returns to inactive state, the intermediate signal DSELIST <3> becomes inactivated at the next falling edge of the clock signal CK2. Instead, the intermediate signal DSELIST <0> becomes activated. Similarly, each time a falling edge of the clock signal CK2 appears, the intermediate signals are sequentially and repeatedly activated in the following order: the intermediate signal DSELIST <1>, the intermediate signal DSELIST <2>, the intermediate signal DSELIST <3>, . . . . The active period of each signal is equal in length to one cycle of the clock signal CK2, which is equivalent to eight cycles of the clock signal CK_00.

Returning to FIG. 5, the decoder 104 is a circuit that generates the slice identification information SID <3:0> based on the layer addresses LID stored in the layer address generating circuit 46 shown in FIG. 4. In this case, the layer addresses LID are two-bit information because the number of core chips stacked is four.

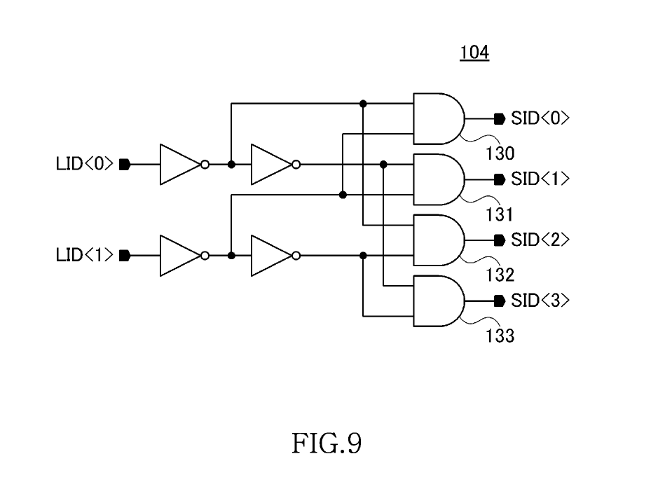

As shown in FIG. 9, the decoder 104 includes AND circuits 130 to 133. An inverted value of the layer address LID<0> and an inverted value of the layer address LID<1> are input into the AND circuit 130, the layer address LID<0> and the inverted value of the layer address LID<1> into the AND circuit 131, the inverted value of the layer address LID<0> and the layer address LID<1> into the AND circuit 132, and the layer address LID<0> and the layer address LID<1> into the AND circuit 133. Each piece of the slice identification information SID<3:0> is taken out from the output terminals of the AND circuits 130 to 133. According to the above configuration, the correlation between the layer addresses LID <1:0> and the slice identification information SID<3:0> turns out to be that shown in Table 1.

TABLE 1

| Core Chips | LID<1> | LID<0> | SID<3> | SID<2> | SID<1> | SID<0> |
|---|---|---|---|---|---|---|
| CC0 | 0 | 0 | 0 | 0 | 0 | 1 |
| CC1 | 0 | 1 | 0 | 0 | 1 | 0 |
| CC2 | 1 | 0 | 0 | 1 | 0 | 0 |
| CC3 | 1 | 1 | 1 | 0 | 0 | 0 |

Returning to FIG. 5, the multiplexer 105 is a circuit that receives the intermediate signals DSELIST <3:0> and the slice identification information SID <3:0>, and generates the output period indication signal DSELSIDT, which indicates the output period of the read data.

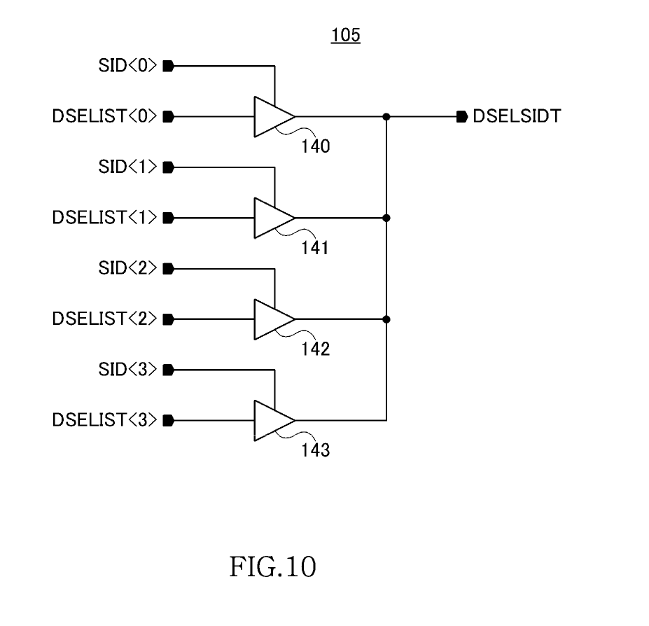

As shown in FIG. 10, the multiplexer 105 includes three-state buffers 140 to 143. To the input terminals of the three-state buffers 140 to 143, the intermediate signals DSELIST <3:0> are respectively input. To the control terminals of the three-state buffers 140 to 143, the slice identification information SID<0> to SID<3> are respectively input. The output period indication signal DSELSIDT is a signal that is generated by combining the output signals of the three-state buffers 140 to 143. According to the above configuration, the output period indication signal DSELSIDT becomes a signal equal to the intermediate signal DSELIST <0> in the core chip CC0, a signal equal to the intermediate signal DSELIST <1> in the core chip CC1, a signal equal to the intermediate signal DSELIST <2> in the core chip CC2, and a signal equal to the intermediate signal DSELIST <3> in the core chip CC3.

Returning to FIG. 5, the AND operation circuit 106 is a circuit that receives the intermediate signals DSELI0T <3:0> and the intermediate signal DSELIST <0>, and generates input timing indication signals DSELIT<3:0>. The AND operation circuit 107 is a circuit that receives the intermediate signals DSELI0T <3:0> and the output period indication signal DSELSIDT, and generates output timing indication signals DSELOT<3:0>.

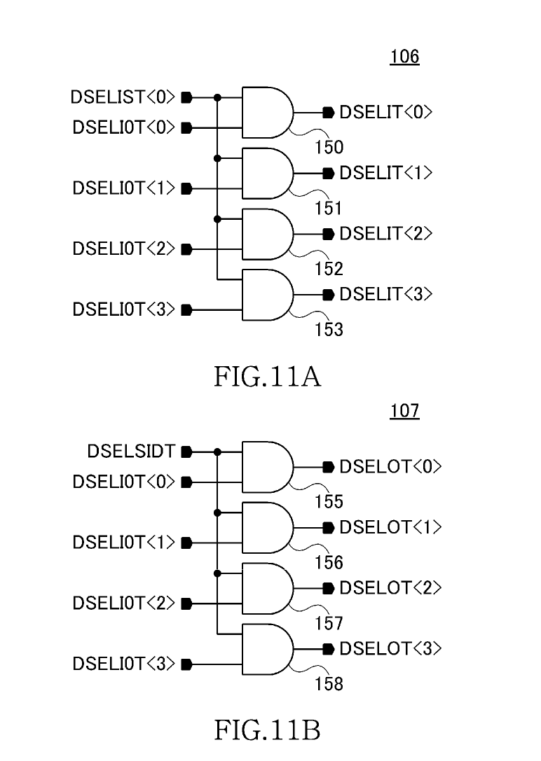

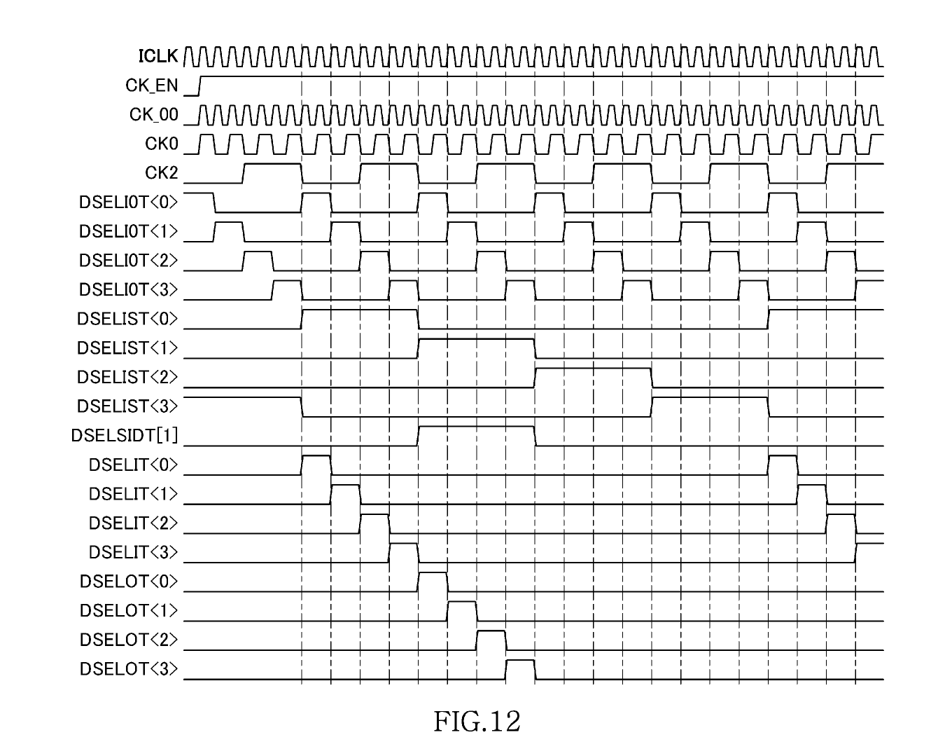

As shown in FIG. 11A, the AND operation circuit 106 includes AND circuits 150 to 153. To the AND circuits 150 to 153, the intermediate signals DSELI0T <3:0> are respectively input. Moreover, the intermediate signal DSELIST <0> is supplied in common to the AND circuits 150 to 153. The input timing indication signals DSELIT<3:0> are respectively taken out from the output terminals of the AND circuits 150 to 153. Accordingly, as shown in FIG. 12, the input timing indication signals DSELIT<3:0> become signals that are equal to the intermediate signals DSELI0T <3:0> during a period of time when the intermediate signal DSELIST <0> is activated; during the other periods, the input timing indication signals DSELIT<3:0> are fixed to LOW. A period of time when the input timing indication signals DSELIT<3:0> are activated is common between the core chips.

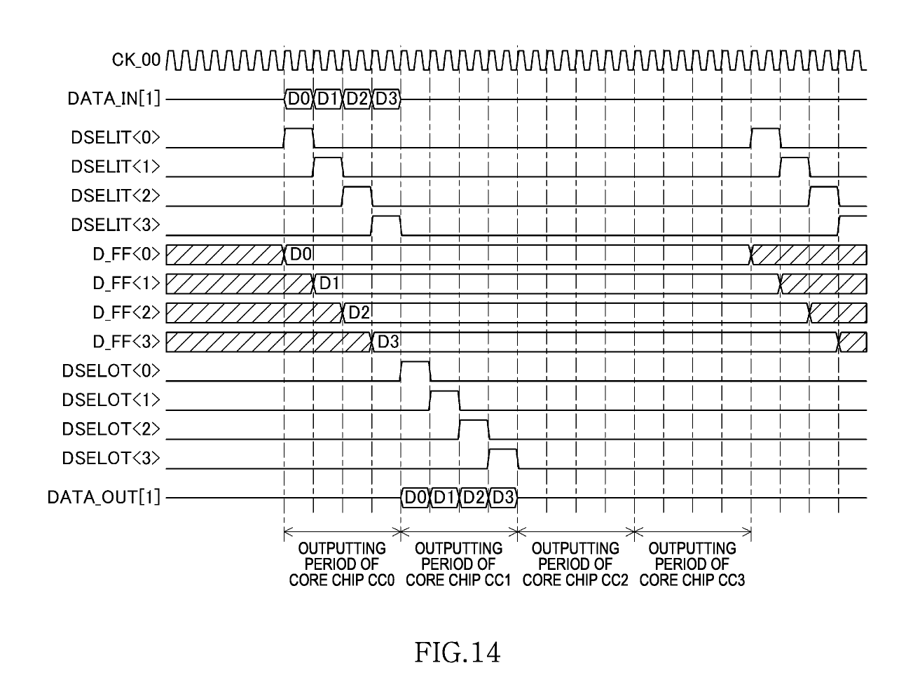

As shown in FIG. 11B, the AND operation circuit 107 includes AND circuits 155 to 158. To the AND circuits 155 to 158, the intermediate signals DSELI0T <3:0> are respectively input. Moreover, the output period indication signal DSELSIDT is supplied in common to the AND circuits 155 to 158. The output timing indication signals DSELOT<3:0> are respectively taken out from the output terminals of the AND circuits 155 to 158. Accordingly, as shown in FIG. 12, the output timing indication signals DSELOT<3:0> become signals that are equal to the intermediate signals DSELI0T <3:0> during a period of time when the output period indication signal DSELSIDT is activated; during the other periods, the output timing indication signals DSELOT<3:0> are fixed to LOW. A period of time when the output timing indication signals DSELOT<3:0> are activated differs between the core chips. More specifically, the output timing indication signals DSELOT<3:0> are sequentially activated from the core chips CC0 to CC3 in that order. It is noted that the numbers in square brackets, which are added to the ends of some signals in FIG. 12 and after-mentioned FIG. 14, indicate core chips that are associated with the signals.

Returning to FIG. 5, the FIFO 108 is a circuit that receives data (read data) stored in the memory cell array 50 (FIG. 4) through the column decoder 52, and outputs the data to the data latch circuit 25 in the interface chip IF through the data current paths DL. As described above, the data current paths DL are so formed as to contain the through silicon vias TSV1 of a type shown in FIG. 2A, and are shared by the core chips. The timing at which the FIFO 108 receives the read data from the column decoder 52 is controlled by the input timing indication signals DSELIT<3:0>. The timing at which the FIFO 108 outputs the read data to the data current paths DL is controlled by the output timing indication signals DSELOT<3:0>.

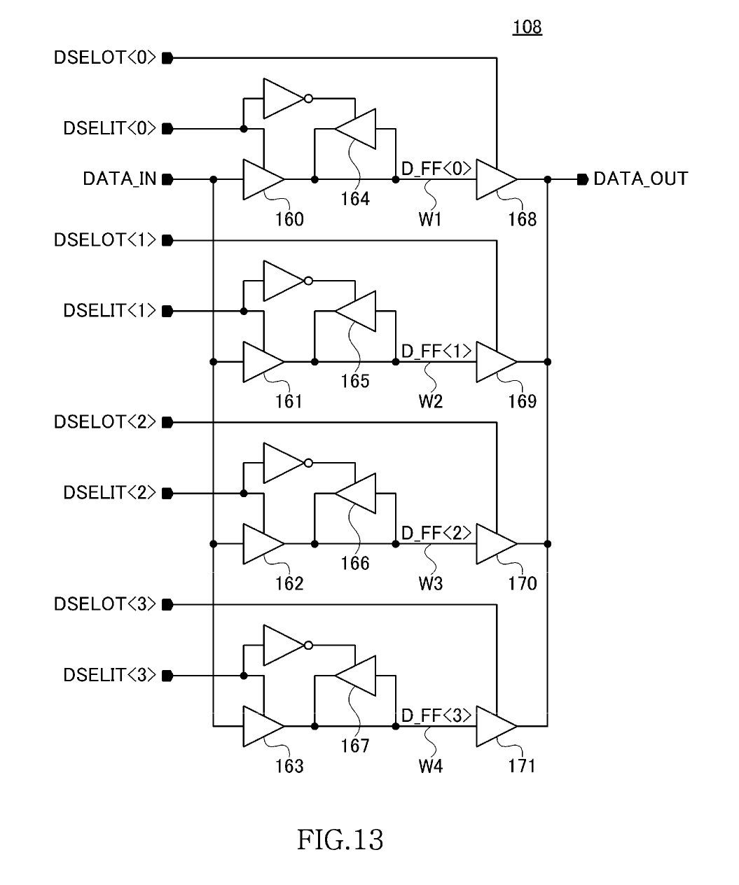

As shown in FIG. 13, the FIFO 108 includes three-state buffers 160 to 171. To the input terminals of the three-state buffers 160 to 163, data DATA_IN, which are supplied from the column decoder 52, are supplied in common. To the control terminals of the three-state buffers 160 to 163, the input timing indication signals DSELIT<0> to DSELIT<3> are respectively supplied. The input terminals of the three-state buffers 168 to 171 are connected to the output terminals of the three-state buffers 160 to 163, respectively, via lines W1 to W4. To the control terminals of the three-state buffers 168 to 171, the output timing indication signals DSELOT<0> to DSELOT<3> are respectively supplied. The input terminals of the three-state buffers 164 to 167 are connected to the input terminals of the three-state buffers 168 to 171. Both the output and input terminals of the three-state buffer 164 are connected to the line W1. However, the output terminal is connected to a position that is closer to an input end of the line W1 than a corresponding input terminal (or to a position that is closer to the output terminal of the three-state buffer 160). The same is true for the three-state buffers 165 to 167 except that the three-state buffers 165 to 167 are connected to the lines W2 to W4, respectively. To the control terminals of the three-state buffers 164 to 167, inverted signals of the input timing indication signals DSELIT<0> to DSELIT<3> are respectively supplied.

As shown in FIG. 14, the data DATA_IN consist of four-bit data D0 to D3, which are output from the memory cell array 50 (FIG. 4) in a burst mode. The active period of each set of data is equal to two cycles of the clock signal CK_00, as shown in FIG. 14.

The control logic circuit 63 shown in FIG. 4, in response to receiving a read command that indicates simultaneous outputting, controls the row control circuit 61 and the column control circuit 62 to transfer data D0 to D3 from the four memory cells specified by the address signals into the sense circuit 53 in such a way that the data are temporarily stored therein: the data D0 to D3 are four bits in total, with each bit read from each of the memory cells. Then, as shown in FIG. 14, the control logic circuit 63 controls a column switch in the column decoder 52 so as to input the data D0 to D3 in a burst mode into the input terminals of the FIFO 108 at the timings at which the input timing indication signals DSELIT<0> to DSELIT<3> each are activated. Thus, the FIFO 108 can receive the data D0 to D3 at the timings at which the input timing indication signals DSELIT<0> to DSELIT<3> each are activated.

The data D0 that are input in synchronization with the input timing indication signal DSELIT<0> are held by the line W1 as hold signal D_FF<0> until the input timing indication signal DSELIT<0> becomes activated again, as shown in FIG. 14. The same is true for the data D1 to D3. As for the hold signals D_FF<0> to D_FF<3> corresponding to the data D0 to D3, FIG. 14 shows the periods during which the corresponding data are held.

If the output timing indication signals DSELOT<3:0> become activated during the periods when the data D0 to D3 are held, the three-state buffers 168 to 171 are sequentially activated in response to the activation. As a result, as shown in FIG. 14, the four-bit data DATA_OUT are output in a burst mode from the FIFO 108.

According to the above configuration, the data DATA_OUT (read data) that are output from the core chips CC0 to CC3 are output in a serial manner. That is, as shown in FIG. 14, first the four-bit read data are output in a burst mode from the core chip CC0. Then, the four-bit read data are output in a burst mode from the core chip CC1. Subsequently, the four-bit read data are output in a burst mode from the core chip CC2. Finally, the four-bit read data are output in a burst mode from the core chip CC3. The read data, which are output in a serial manner from each of the core chips as described above, are supplied to the data latch circuit 25 shown in FIG. 4 via the current paths that contain the through silicon vias TSV1 of a type shown in FIG. 2A.

As described above, the above description focuses on one data current path. To the data latch circuit 25, the 16-bit read data (=the number of core chips, 4, ×, the number of burst-output bits, 4) are supplied in a serial manner via one data current path. However, in reality, as described above, there are the data current paths, the number of which can be calculated by multiplying the number of banks, the pre-fetch number, and the number of data input/output terminals; through each of the data current paths, the 16-bit read data are supplied in a serial manner from each of the core chips. The data latch circuit 25 and the input/output buffer circuit 23 function as output circuits (second output circuits) that output the read data, which are supplied in parallel from each of the core chips via each of a plurality of data current paths as described above, to the outside via each of the data input/output terminals 14. More specifically, the data latch circuit 25 converts the read data, which are supplied from each of the core chips, into a serial form for each of the data input/output terminals 14 before supplying to the input/output buffer circuit 23. Then, the input/output buffer circuit 23 carries out an output operation in synchronization with the input/output clock signal LCLK. Therefore, the read data that are output from each of the core chips are output from each of the data input/output terminals 14 in synchronization with the external clock signals CK and /CK.

As described above, the semiconductor device 10 of the present embodiment can output the read data in a serial manner and without leaving a time interval between the read data from each of the core chips. Therefore, even if the data current paths are shared by the core chips, the collision of the read data does not occur. Moreover, no overhead occurs. Thus, it is possible to minimize the space occupied by the data current paths, as well as to prevent a decline in the operating speed.

It is apparent that the present invention is not limited to the above embodiments, but may be modified and changed without departing from the scope and spirit of the invention.

For example, according to the above embodiment, each core chip outputs the four-bit read data in a burst mode via one data current path. However, the read data that each core chip outputs via one data current path may be made up of one or more bits. In case the read data that are output as described above are made up of two or more bits, each core chip outputs the data in a burst mode.

What is claimed is:

1. A semiconductor device comprising:
an interface chip; and
a plurality of core chips stacked to the interface chip, the core chips having different chip identification information from one another, at least one of the core chips including a penetration electrode that penetrates therethrough, the penetration electrode forming a part of a data signal path that electrically connects the interface chip to the core chips in common, wherein
the interface chip includes a command decoder simultaneously supplying a read command to the core chips, and
each of the core chips includes:
a memory cell array having a plurality of memory cells;
a chip identification information storage unit storing the chip identification information assigned thereto; and
a first output circuit reading a read data from the memory cell array in response to the read command, the first output circuit outputting the read data to the interface chip via the data signal path at a timing corresponding to the chip identification information that is stored in the chip identification information storage unit.

2. The semiconductor device as claimed in claim 1, wherein the first output circuits of the core chips output the read data to the data signal path at different timings from one another so as to prevent the read data outputted from different core chips from racing on the data signal path.

3. The semiconductor device as claimed in claim 1, wherein
two or more of the core chips include a penetration electrode, respectively,
the data signal path includes a plurality of penetration electrodes electrically connected to one another, and
the plurality of penetration electrodes are vertically aligned.

4. The semiconductor device as claimed in claim 1, wherein the first output circuit reads a plurality of read data from the memory cell array in response to the read command, the first output circuit outputting the plurality of read data in serial to the interface chip via the data signal path at the timing corresponding to the chip identification information stored in the chip identification information storage unit.

5. The semiconductor device as claimed in claim 1, further comprising a data input/output terminal,
wherein the interface chip includes a second output circuit outputting the read data, which are output from each of the plurality of core chips, to outside through the data input/output terminal.

6. A semiconductor device comprising:
an interface chip; and
a plurality of core chips stacked to the interface chip, the core chips having different chip identification information from one another, at least one of the core chips including a plurality of penetration electrodes that penetrate therethrough, the penetration electrodes forming a part of a plurality of data signal paths each of which electrically connects the interface chip to the core chips in common, wherein
the interface chip includes a command decoder simultaneously supplying a read command to the core chips, and
each of the core chips includes:
a memory cell array having a plurality of memory cells;
a chip identification information storage unit storing the chip identification information assigned thereto; and
a first output circuit reading a plurality of read data from the memory cell array in response to the read command, the first output circuit outputting the plurality of read data to the interface chip via the data signal paths at a timing corresponding to the chip identification information that is stored in the chip identification information storage unit.

7. The semiconductor device as claimed in claim 6, further comprising a data input/output terminal,
wherein the interface chip includes a second output circuit outputting the plurality of read data, which are supplied in parallel via the plurality of data current paths, to outside in serial through the data input/output terminal.

8. The semiconductor device as claimed in claim 6, wherein the first output circuits of the core chips output the plurality of read data to the data signal paths at different timings from one another so as to prevent the read data outputted from different core chips from racing on the data signal paths.

9. The semiconductor device as claimed in claim 6, wherein
two or more of the core chips include a plurality of penetration electrodes, respectively,
each of the data signal paths includes a plurality of penetration electrodes electrically connected to one another, and
the plurality of penetration electrodes constituting the same data signal path are vertically aligned.

10. A semiconductor device comprising:
a first semiconductor chip outputting a read command and a clock signal;
a plurality of second semiconductor chips stacked to the first semiconductor chip, each of the second semiconductor chips performing a read operation to read out a data signal stored therein in response to the read command; and
a signal path electrically connected between the first and second semiconductor chips, wherein
each of the second semiconductor chips includes:
a counter circuit performing a count operation in response to the clock signal to generate a count signal; and
an output control circuit outputs the data signal to the signal path when the count signal indicates a predetermined value, and
the predetermined values of the second semiconductor chips are different from one another.

11. The semiconductor device as claimed in claim 10, wherein the count signals of the second semiconductor chips indicate the same value as one another.

12. The semiconductor device as claimed in claim 10, wherein at least one of the second semiconductor chips is provided with a penetration electrode that penetrate therethrough, the signal path including the penetration electrode.
